(19) United States
(12) Patent Application Publication
(10) Pub. No.: US 2026/0013191 A1
(43) Pub. Date: Jan. 8, 2026

(54) SEMICONDUCTOR STRUCTURE AND METHOD FOR MANUFACTURING THE SAME

(71) Applicant: ENKRIS SEMICONDUCTOR, INC., Suzhou (CN)

(72) Inventor: Kai CHENG, Suzhou (CN)

(73) Assignee: ENKRIS SEMICONDUCTOR, INC., Suzhou (CN)

(21) Appl. No.: 18/819,138

(22) Filed: Aug. 29, 2024

(30) Foreign Application Priority Data
Jul. 8, 2024 (CN) 202410909907.3

(51) Int. Cl. H01L 29/16; H01L 21/02; H01L 29/04; H01L 29/06; H01L 29/778; H03H 9/02

(52) U.S. Cl. CPC H10D 62/8303; H01L 21/02211; H01L 21/02376; H01L 21/02447; H03H 9/02976; H10D 30/47; H10D 62/117; H10D 62/405; H10D 62/8325

(57) ABSTRACT

A semiconductor structure includes a diamond substrate, a SiC intermediate layer, and a device layer that are stacked. The diamond substrate includes a plurality of first grooves on a side close to the SiC intermediate layer, the plurality of first grooves are spaced apart, the SiC intermediate layer includes a plurality of second grooves on a side close to the diamond substrate, the plurality of second grooves are spaced apart, and the plurality of first grooves and the plurality of second grooves are in a one-to-one correspondence and form a plurality of cavities. Adopting the structure including the diamond substrate, the SiC intermediate layer, and the device layer in the present disclosure may reduce defects caused by a lattice mismatch and a thermal mismatch between a substrate and a device, thereby improving overall quality and reliability of a semiconductor structure.

### CROSS-REFERENCE TO RELATED APPLICATIONS

This application claims priority to Chinese Patent Application No. 202410909907.3, filed on Jul. 8, 2024, the entire content of which is incorporated herein by reference.

### TECHNICAL FIELD

The present disclosure relates to the field of semiconductor technologies, and in particular, to a semiconductor structure and a method for manufacturing the same.

### BACKGROUND

At present, when a device made of an III-V group material is prepared, a heterogeneous substrate with a lattice mismatch and a thermal expansion coefficient mismatch is generally used for epitaxial growth of the III-V group material, but there are relatively large lattice mismatch and thermal expansion coefficient mismatch between the heterogeneous substrate and the III-V group material, thereby resulting in poor quality and low reliability of the device made of the III-V group material on the heterogeneous substrate.

### SUMMARY

In view of this, embodiments of the present disclosure provide a semiconductor structure and a method for manufacturing the same, to manufacture a high-quality device made of an III-V group material on a heterogeneous substrate.

According to an aspect of the present disclosure, an embodiment of the present disclosure provides a semiconductor structure, including: a diamond substrate, a SiC intermediate layer, and a device layer that are stacked; and the diamond substrate includes a plurality of first grooves on a side close to the SiC intermediate layer, the plurality of first grooves are spaced apart, the SiC intermediate layer includes a plurality of second grooves on a side close to the diamond substrate, the plurality of second grooves are spaced apart, and the plurality of first grooves and the plurality of second grooves are in a one-to-one correspondence and form a plurality of cavities.

As an optional embodiment, a surface crystal orientation of the diamond substrate includes a [100] crystal orientation with a bias angle.

As an optional embodiment, the bias angle ranges from 0° to 4°.

As an optional embodiment, along a direction from the diamond substrate to the device layer, a depth of each first groove of the plurality of first grooves is less than or equal to a thickness of the diamond substrate.

As an optional embodiment, along a direction from the diamond substrate to the device layer, a depth of each second groove of the plurality of second grooves is less than a thickness of the SiC intermediate layer.

As an optional embodiment, on a plane where the diamond substrate is located, shapes of projections of the plurality of cavities include at least one of triangle, square, hexagon, circle, strip shape, or mesh shape.

As an optional embodiment, on a plane where the diamond substrate is located, an amount of projections of the plurality of cavities per unit area gradually increases from a center to an edge.

As an optional embodiment, on a plane where the diamond substrate is located, sizes of projections of the plurality of cavities per unit area gradually increases from a center to an edge.

As an optional embodiment, the semiconductor structure is a High Electron Mobility Transistor (HEMT) structure, and the device layer includes a channel layer and a barrier layer that are stacked sequentially, and a source electrode, a drain electrode and a gate electrode that are located on the barrier layer.

As an optional embodiment, the semiconductor structure is a Surface Acoustic Wave (SAW) structure, and the device layer includes a piezoelectric layer and an interdigital transducer that are stacked sequentially.

As an optional embodiment, a plurality of interdigital electrodes of the interdigital transducer and the plurality of cavities are in a one-to-one correspondence.

As an optional embodiment, along a direction from an interdigital electrode to another interdigital electrode, a width of each interdigital electrode is the same as a width of a corresponding cavity.

According to another aspect of the present disclosure, an embodiment of the present disclosure provides a method for manufacturing a semiconductor structure, including: providing a diamond substrate; etching a plurality of first grooves on a surface of the diamond substrate, the plurality of first grooves being spaced apart; laterally epitaxially growing a SiC intermediate layer on a growth surface, between the plurality of first grooves, of the diamond substrate, a side, away from the diamond substrate, of the SiC intermediate layer being planar, the SiC intermediate layer including a plurality of second grooves on a side close to the diamond substrate, the plurality of second grooves being spaced apart, and the plurality of first grooves and the plurality of second grooves being in a one-to-one correspondence and forming a plurality of cavities; and disposing a device layer on the SiC intermediate layer.

As an optional embodiment, the method for manufacturing the semiconductor structure further includes: performing high-temperature heat treatment on the growth surface of the diamond substrate in a silane atmosphere, to form a silicon carbide coating layer.

As an optional embodiment, the disposing a device layer on the SiC intermediate layer includes: disposing the device layer on the SiC intermediate layer, the device layer including a channel layer and a barrier layer that are stacked sequentially, and a source electrode, a drain electrode and a gate electrode that are located on the barrier layer.

As an optional embodiment, the disposing a device layer on the SiC intermediate layer includes: disposing the device layer on the SiC intermediate layer, the device layer including a piezoelectric layer and an interdigital transducer that are stacked sequentially.

As an optional embodiment, a surface crystal orientation of the diamond substrate includes a [100] crystal orientation with a bias angle.

As an optional embodiment, the bias angle ranges from 0° to 4°.

As an optional embodiment, along a direction from the diamond substrate to the device layer, a depth of each first groove of the plurality of first grooves is less than or equal to a thickness of the diamond substrate.

As an optional embodiment, on a plane where the diamond substrate is located, shapes of projections of the plurality of first grooves include at least one of triangle, square, hexagon, circle, strip shape, or mesh shape.

### BRIEF DESCRIPTION OF THE DRAWINGS

FIG. 1 shows a schematic structural diagram of a semiconductor structure according to an embodiment of the present disclosure.

FIG. 2a to FIG. 2f show schematic top-view diagrams of semiconductor structures according to some embodiments of the present disclosure.

FIG. 3a and FIG. 3b show schematic top-view diagrams of semiconductor structures according to some embodiments of the present disclosure.

FIG. 4 shows a schematic structural diagram of a semiconductor structure according to an embodiment of the present disclosure.

FIG. 5 shows a schematic structural diagram of a semiconductor structure according to an embodiment of the present disclosure.

FIG. 6 shows a flowchart of a method for manufacturing a semiconductor structure according to an embodiment of the present disclosure.

FIG. 7 to FIG. 9 show schematic structural diagrams of intermediate structures of a semiconductor structure during a manufacturing process according to an embodiment of the present disclosure.

### DETAILED DESCRIPTION OF THE EMBODIMENTS

The following clearly and completely describes technical solutions in the embodiments of the present disclosure with reference to the accompanying drawings in the embodiments of the present disclosure. Apparently, the described embodiments are a part rather than all of the embodiments of the present disclosure. All other embodiments obtained by a person skilled in the art based on the embodiments of the present disclosure without creative efforts shall fall within the protection scope of the present disclosure.

A material of a substrate, used for epitaxially growing an III-V group material by using a Metal-organic Chemical Vapor Deposition (MOCVD) method, should preferably be the same material as the III-V group material, so that a lattice mismatch between a device and the substrate is small and a thermal expansion coefficient between a device and the substrate is low. However, due to an extremely high melting point and a very large nitrogen saturation vapor pressure of the III-V group material such as GaN or AlN, it is difficult to obtain a homogeneous substrate with a large area and high quality. At present, due to the lack of a substrate that can achieve a lattice match with the III-V group material, when a device made of the III-V group material is prepared, a heterogeneous substrate with a lattice mismatch and a thermal expansion coefficient mismatch is generally used for epitaxial growth of the III-V group material, but there are relatively large lattice mismatch and thermal expansion coefficient mismatch between the most commonly used heterogeneous substrate, such as sapphire or silicon substrates, and the III-V group material, thereby resulting in poor quality and low reliability of the device made of the III-V group material on the heterogeneous substrate.

To manufacture a high-quality device made of an III-V group material on a heterogeneous substrate, the present disclosure provides a semiconductor structure and a method for manufacturing the same. The semiconductor structure includes a diamond substrate, a SiC intermediate layer, and a device layer that are stacked; and the diamond substrate includes a plurality of first grooves on a side close to the SiC intermediate layer, the plurality of first grooves are spaced apart, the SiC intermediate layer includes a plurality of second grooves on a side close to the diamond substrate, the plurality of second grooves are spaced apart, and the plurality of first grooves and the plurality of second grooves are in a one-to-one correspondence and form a plurality of cavities. Adopting the structure including the diamond substrate, the SiC intermediate layer, and the device layer in the present disclosure may reduce defects caused by a lattice mismatch and a thermal mismatch between a substrate and a device, thereby improving overall quality and reliability of a semiconductor structure.

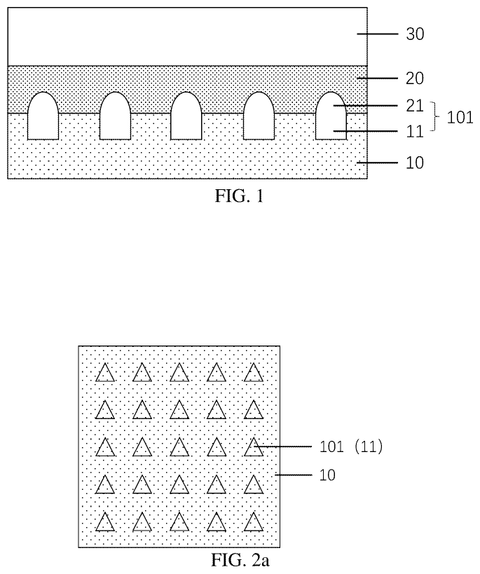

The semiconductor structure and the method for manufacturing the same mentioned in the present disclosure may be further illustrated with examples in conjunction with FIG. 1 to FIG. 9 below.

FIG. 1 shows a schematic structural diagram of a semiconductor structure according to an embodiment of the present disclosure. As shown in FIG. 1, the semiconductor structure includes a diamond substrate 10, a SiC intermediate layer 20, and a device layer 30 that are stacked; and the diamond substrate 10 includes a plurality of first grooves 11 on a side close to the SiC intermediate layer 20, the plurality of first grooves 11 are spaced apart, the SiC intermediate layer 20 includes a plurality of second grooves 21 on a side close to the diamond substrate 10, the plurality of second grooves 21 are spaced apart, the plurality of first grooves 11 and the plurality of second grooves 21 are in a one-to-one correspondence and form a plurality of cavities 101, and one cavity 101 is formed by one first groove 11 and a corresponding second groove 21.

In this embodiment, a surface crystal orientation of the diamond substrate 10 includes a [100] crystal orientation with a bias angle. Using diamond with [100] the crystal orientation is beneficial for epitaxial growth and may improve a heat dissipation capability of a device. The bias angle ranges from 0° to 4°, and the bias angle of the substrate with [100] the crystal orientation may have an effect on a growth mode of the diamond. When the bias angle is relatively small, a step flow on a surface of the diamond moves at a relatively slow rate; and when the bias angle is relatively large, the step flow on the surface of the diamond moves at a relatively fast rate, and lattice defects and internal stresses continue to accumulate, thereby resulting in a decrease in crystallization quality of an epitaxial layer, and therefore, the diamond substrate 10 with the bias angle ranging from 0° to 4° is provided.

In this embodiment, on the one hand, disposal of the SiC intermediate layer 20 may reduce a lattice mismatch between the diamond substrate 10 and the device layer 30, so as to effectively reduce generation of defects; and on the other hand, the existence of an insulating SiC material may effectively reduce high-frequency electrical leakage of a device, so as to suppress generation of related noise waves and improve stability of a device.

In this embodiment, as shown in FIG. 1, along a direction from the diamond substrate 10 to the device layer 30, a depth of each first groove 11 is less than or equal to a thickness of the diamond substrate 10, and a depth of each second groove 21 is less than a thickness of the SiC intermediate layer 20. The plurality of first grooves 11 and the plurality of second grooves 21 are in a one-to-one correspondence and form the plurality of cavities 101, and disposal of the plurality of cavities 101 may further alleviate mismatch issues, thereby reducing a fragmentation phenomenon during the subsequent preparation process due to an excessive stress in the device layer 30, and further effectively improving a yield of a device structure. Due to the plurality of first grooves 11 in the diamond substrate 10, the SiC intermediate layer 20 is laterally epitaxially grown on the diamond substrate 10, and is grown in a merged manner on the diamond substrate 10, which may further reduce a dislocation density of the SiC intermediate layer 20, thereby improving crystal quality of the SiC intermediate layer 20, and further enhancing quality of the device layer 30 on the SiC intermediate layer 20.

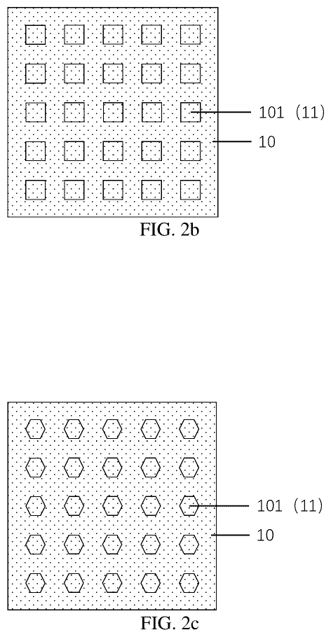

In one embodiment, FIG. 2a to FIG. 2f show schematic top-view diagrams of semiconductor structures according to some embodiments of the present disclosure. On a plane where the diamond substrate 10 is located, shapes of projections of the plurality of cavities 101 include at least one of triangle (shown in FIG. 2a), square (shown in FIG. 2b), hexagon (shown in FIG. 2c), circle (shown in FIG. 2d), strip shape (shown in FIG. 2e), or mesh shape (shown in FIG. 2f). The shapes of the projections, on the plane where the diamond substrate 10 is located, of the plurality of cavities 101 are not specifically limited by the present disclosure.

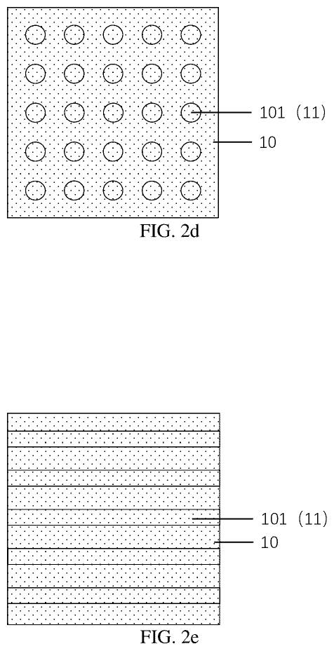

In one embodiment, FIG. 3a and FIG. 3b show schematic top-view diagrams of semiconductor structures according to some embodiments of the present disclosure. On a plane where the diamond substrate 10 is located, an amount of projections of the plurality of cavities 101 per unit area gradually increases from a center to an edge (shown in FIG. 3a), or sizes of projections of the plurality of cavities 101 per unit area gradually increases from a center to an edge (shown in FIG. 3b). Adjusting the sizes and the distribution of the plurality of cavities 101 may further improve overall stress distribution of a device structure, so as to enhance quality and reliability of a device structure.

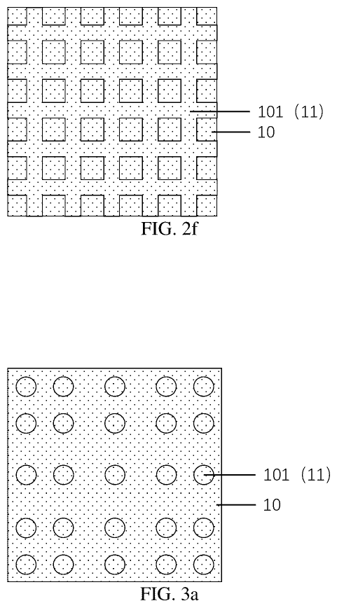

In one embodiment, FIG. 4 shows a schematic structural diagram of a semiconductor structure according to an embodiment of the present disclosure. As shown in FIG. 4, the semiconductor structure is a High Electron Mobility Transistor (HEMT) structure. The device layer 30 includes a channel layer 31 and a barrier layer 32 that are stacked sequentially, and a source electrode 33, a drain electrode 34 and a gate electrode 35 that are located on the barrier layer 32. Materials of the channel layer 31 and the barrier layer 32 are GaN-based materials, for example, the material of the channel layer 31 is GaN, and the material of the barrier layer 32 is AlGaN. The HEMT structure provided by the present disclosure has a low mismatch between the substrate layer and the device layer, and therefore, the overall HEMT structure has good quality and high reliability.

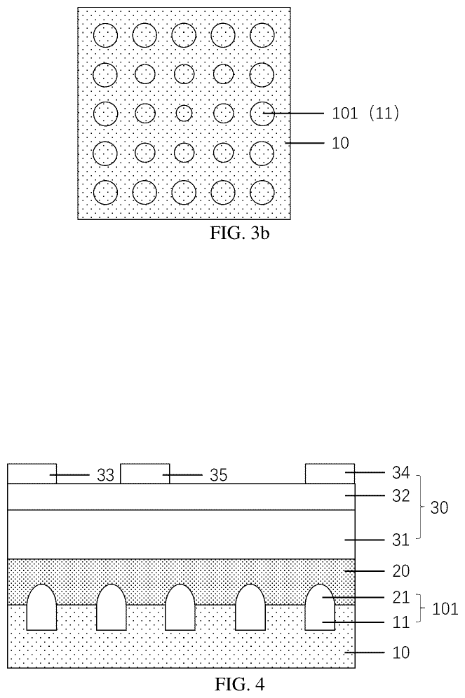

In one embodiment, FIG. 5 shows a schematic structural diagram of a semiconductor structure according to an embodiment of the present disclosure. As shown in FIG. 5, the semiconductor structure is a Surface Acoustic Wave (SAW) structure. The device layer 30 includes a piezoelectric layer 36 and an interdigital transducer 37 that are stacked sequentially. A material of the piezoelectric layer 36 includes aluminum nitride or scandium-doped aluminum nitride. As shown in FIG. 5, a plurality of interdigital electrodes of the interdigital transducer 37 and the plurality of cavities 101 are in a one-to-one correspondence, and along a direction from an interdigital electrode to another interdigital electrode, a width of each interdigital electrode is the same as a width of a corresponding cavity 101. The interdigital transducer 37 forms an electric field under the action of electrical signals, which produces shear waves and longitudinal waves on the piezoelectric layer 36. The longitudinal waves propagate towards a direction perpendicular to the piezoelectric layer 36, and therefore, the cavities 101 corresponding to positions of the interdigital electrodes are disposed, so that the longitudinal waves reflect back to the piezoelectric layer 36 through the cavities 101, thereby enhancing an energy of the shear waves, and further reducing a transmission loss of a surface acoustic wave resonator. The piezoelectric layer 36 generates longitudinal waves under the influence of the interdigital electrodes, and when the width of the cavity 101 is the same as the width of the interdigital electrode, the cavities 101 may precisely reflect the longitudinal waves, further reducing the transmission loss of the surface acoustic wave resonator.

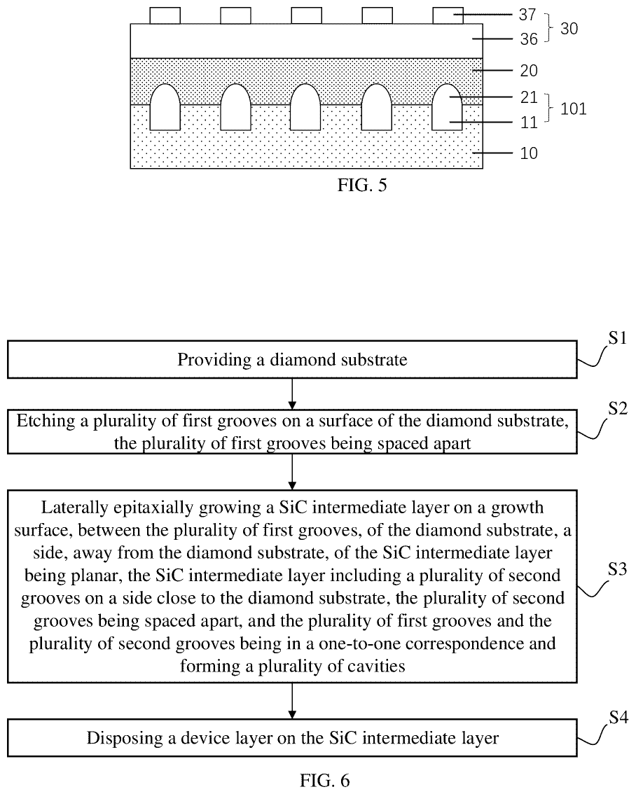

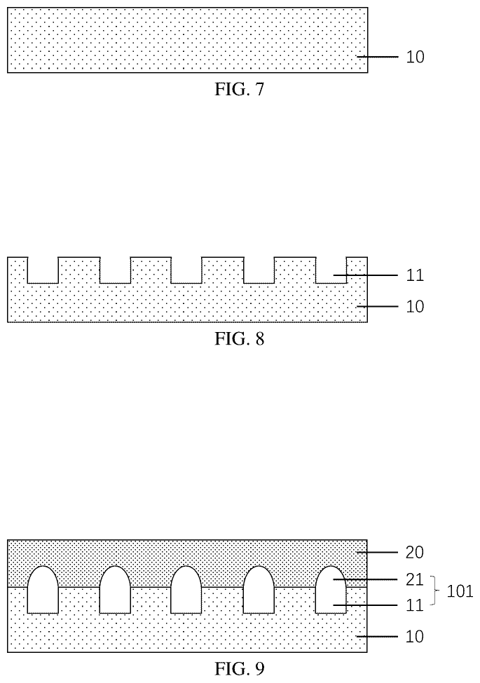

According to another aspect of the present disclosure, FIG. 6 shows a flowchart of a method for manufacturing a semiconductor structure according to an embodiment of the present disclosure. FIG. 7 to FIG. 9 show schematic structural diagrams of intermediate structures of a semiconductor structure during a manufacturing process according to an embodiment of the present disclosure. As shown in FIG. 6, the method for manufacturing the semiconductor structure according to an embodiment of the present disclosure includes the following content.
Step S1: providing a diamond substrate.

As shown in FIG. 7, the diamond substrate 10 is provided. A surface crystal orientation of the diamond substrate 10 includes a [100] crystal orientation with a bias angle. Using diamond with the [100] crystal orientation is beneficial for epitaxial growth and may improve a heat dissipation capability of a device. The surface crystal orientation of the diamond substrate 10 has the bias angle ranging from 0° to 4° from a positive crystal orientation, and the bias angle of the substrate with the [100] crystal orientation may have an effect on a growth mode of the diamond.

When the bias angle is relatively small, a step flow on a surface of the diamond moves at a relatively slow rate; and when the bias angle is relatively large, the step flow on the surface of the diamond moves at a relatively fast rate, and lattice defects and internal stresses continue to accumulate, thereby resulting in a decrease in crystallization quality of an epitaxial layer, and therefore, the diamond substrate 10 with the bias angle ranging from 0° to 4° is provided.
Step S2: etching a plurality of first grooves on a surface of the diamond substrate, the plurality of first grooves being spaced apart.

As shown in FIG. 8, the surface of the diamond substrate 10 is etched to form the plurality of first grooves 11 that are spaced apart, and a depth of each first groove 11 is less than or equal to a thickness of the diamond substrate 10.

In one embodiment, after the step S2, the method for manufacturing the semiconductor structure further includes performing high-temperature heat treatment on the growth surface of the diamond substrate 10 in a silane atmosphere, to form a silicon carbide coating layer, which is beneficial for the subsequent growth of the SiC intermediate layer 20, thereby improving quality of the SiC intermediate layer 20.
Step S3: laterally epitaxially growing a SiC intermediate layer on a growth surface, between the plurality of first grooves, of the diamond substrate, a side, away from the diamond substrate, of the SiC intermediate layer being planar, the SiC intermediate layer including a plurality of second grooves on a side close to the diamond substrate, the plurality of second grooves being spaced apart, and the plurality of first grooves and the plurality of second grooves being in a one-to-one correspondence and forming a plurality of cavities.

As shown in FIG. 9, the SiC intermediate layer 20 is laterally epitaxially grown on the surface, between the plurality of first grooves 11, of the diamond substrate 10, the side, away from the diamond substrate 10, of the SiC intermediate layer 20 is planar, the SiC intermediate layer 20 includes the plurality of second grooves 21 on the side close to the diamond substrate 10, the plurality of second grooves 21 are spaced apart, the plurality of first grooves 11 and the plurality of second grooves 21 are in a one-to-one correspondence and form the plurality of cavities 101, and a depth of each second groove 21 is less than a thickness of the SiC intermediate layer 20. The SiC intermediate layer 20 is laterally epitaxially grown on the diamond substrate 10, and is grown in a merged manner on the diamond substrate 10, so that a dislocation density of the SiC intermediate layer 20 may be reduced, so as to improve crystal quality of the SiC intermediate layer 20, while reducing a lattice mismatch between the diamond substrate 10 and a device layer 30 subsequently grown, so as to effectively reduce generation of defects.
Step S4: disposing a device layer on the SiC intermediate layer.

The device layer 30 is disposed on the SiC intermediate layer 20, to form the semiconductor structure shown in FIG. 1.

In one embodiment, on a plane where the diamond substrate 10 is located, shapes of projections of the plurality of first grooves 11 include at least one of triangle (shown in FIG. 2a), square (shown in FIG. 2b), hexagon (shown in FIG. 2c), circle (shown in FIG. 2d), strip shape (shown in FIG. 2e), or mesh shape (shown in FIG. 2f). The shapes of the projections, on the plane where the diamond substrate 10 is located, of the plurality of first grooves 11 are not specifically limited by the present disclosure.

In one embodiment, on a plane where the diamond substrate 10 is located, an amount of projections of the plurality of first grooves 11 per unit area gradually increases from a center to an edge (shown in FIG. 3a), or sizes of projections of the plurality of first grooves 11 per unit area gradually increases from a center to an edge (shown in FIG. 3b). Adjusting the sizes and the distribution of the plurality of first grooves 11 may adjust sizes and distribution of the plurality of cavities 101, thereby improving overall stress distribution of a device structure, and further enhancing quality and reliability of a device structure.

In one embodiment, the step S4 further includes: disposing the device layer 30 on the SiC intermediate layer 20, and the device layer 30 includes a channel layer 31 and a barrier layer 32 that are stacked sequentially, and a source electrode 33, a drain electrode 34 and a gate electrode 35 that are located on the barrier layer 32, to form the HEMT structure shown in FIG. 4. The HEMT structure provided by the present disclosure has a low mismatch between the substrate layer and the device layer, and therefore, the overall HEMT structure has good quality and high reliability

In one embodiment, step S4 further includes: disposing the device layer 30 on the SiC intermediate layer 20, and the device layer 30 includes a piezoelectric layer 36 and an interdigital transducer 37 that are stacked sequentially, to form the SAW structure shown in FIG. 5. There is a low lattice mismatch between the SiC intermediate layer 20 and the piezoelectric layer 36, which may effectively reduce generation of defects, thereby improving crystal quality of the piezoelectric layer 36. On the one hand, disposing the cavities 101 between the SiC intermediate layer 20 and the diamond substrate 10 may further alleviate mismatch issues, thereby reducing a fragmentation phenomenon during the subsequent preparation process due to an excessive stress, and further effectively improving a yield of a device structure; and on the other hand, disposing the cavities 101 between the SiC intermediate layer 20 and the diamond substrate 10 may reflect acoustic waves, thereby reducing a loss of the acoustic waves, and further improving a Q value of a device structure.

The present disclosure provides a semiconductor structure and a method for manufacturing the same. The semiconductor structure includes a diamond substrate, a SiC intermediate layer, and a device layer that are stacked; and the diamond substrate includes a plurality of first grooves on a side close to the SiC intermediate layer, the plurality of first grooves are spaced apart, the SiC intermediate layer includes a plurality of second grooves on a side close to the diamond substrate, the plurality of second grooves are spaced apart, and the plurality of first grooves and the plurality of second grooves are in a one-to-one correspondence and form a plurality of cavities. On the one hand, disposal of the SiC intermediate layer in the present disclosure may alleviate a lattice mismatch and a thermal mismatch between the diamond substrate and the device layer, thereby effectively reducing generation of microstructural defects such as vacancies, antiphase domains, and rotational domains, and further improving quality of the device layer; and on the other hand, disposing the cavities between the diamond substrate and the SiC intermediate layer in the present disclosure may attenuate a stress transmitted from the device layer to the diamond substrate layer, thereby improving a mechanical strength of the diamond substrate, and further avoiding deformation during the subsequent epitaxial process. In summary, adopting the structure including the diamond substrate, the SiC intermediate layer, and the device layer in the present disclosure may reduce defects caused by a lattice mismatch and a thermal mismatch between a substrate and a device, thereby improving overall quality and reliability of a semiconductor structure.

It should be understood that the terms “including” and its variations used in the present disclosure are open-ended, i.e., “including but not limited to”. The term “an embodiment” means “at least one embodiment”; and the term “another embodiment” means “at least one another embodiment”. In this specification, schematic representations of the above terms do not necessarily refer to the same example or embodiment. Moreover, the specific features, structures, materials, or characteristics described herein may be combined in any suitable manner in any one or more of the examples or embodiments. Furthermore, without conflicting with each other, a person skilled in the art may combine and integrate different examples or embodiments described herein, as well as features of the different examples or embodiments.

The above are only preferred embodiments of the present disclosure and are not intended to limit the present disclosure. Any modifications, equivalent substitutions, etc. made within the spirit and principles of the present disclosure shall be included within the protection scope of the present disclosure.

What is claimed is:

1. A semiconductor structure, comprising:
a diamond substrate, a SiC intermediate layer, and a device layer that are stacked;
wherein the diamond substrate comprises a plurality of first grooves on a side close to the SiC intermediate layer, the plurality of first grooves are spaced apart, the SiC intermediate layer comprises a plurality of second grooves on a side close to the diamond substrate, the plurality of second grooves are spaced apart, and the plurality of first grooves and the plurality of second grooves are in a one-to-one correspondence and form a plurality of cavities.

2. The semiconductor structure according to claim 1, wherein a surface crystal orientation of the diamond substrate comprises a [100] crystal orientation with a bias angle.

3. The semiconductor structure according to claim 2, wherein the bias angle ranges from 0° to 4°.

4. The semiconductor structure according to claim 1, wherein along a direction from the diamond substrate to the device layer, a depth of each first groove of the plurality of first grooves is less than or equal to a thickness of the diamond substrate.

5. The semiconductor structure according to claim 1, wherein along a direction from the diamond substrate to the device layer, a depth of each second groove of the plurality of second grooves is less than a thickness of the SiC intermediate layer.

6. The semiconductor structure according to claim 1, wherein on a plane where the diamond substrate is located, shapes of projections of the plurality of cavities comprise at least one of triangle, square, hexagon, circle, strip shape, or mesh shape.

7. The semiconductor structure according to claim 1, wherein on a plane where the diamond substrate is located, an amount of projections of the plurality of cavities per unit area gradually increases from a center to an edge.

8. The semiconductor structure according to claim 1, wherein on a plane where the diamond substrate is located, sizes of projections of the plurality of cavities per unit area gradually increases from a center to an edge.

9. The semiconductor structure according to claim 1, wherein the semiconductor structure is a High Electron Mobility Transistor (HEMT) structure, and the device layer comprises a channel layer and a barrier layer that are stacked sequentially, and a source electrode, a drain electrode and a gate electrode that are located on the barrier layer.

10. The semiconductor structure according to claim 1, wherein the semiconductor structure is a Surface Acoustic Wave (SAW) structure, and the device layer comprises a piezoelectric layer and an interdigital transducer that are stacked sequentially.

11. The semiconductor structure according to claim 10, wherein a plurality of interdigital electrodes of the interdigital transducer and the plurality of cavities are in a one-to-one correspondence.

12. The semiconductor structure according to claim 11, wherein along a direction from an interdigital electrode to another interdigital electrode, a width of each interdigital electrode is the same as a width of a corresponding cavity.

13. A method for manufacturing a semiconductor structure, comprising:
providing a diamond substrate;
etching a plurality of first grooves on a surface of the diamond substrate, the plurality of first grooves being spaced apart;
laterally epitaxially growing a SiC intermediate layer on a growth surface, between the plurality of first grooves, of the diamond substrate, a side, away from the diamond substrate, of the SiC intermediate layer being planar, the SiC intermediate layer comprising a plurality of second grooves on a side close to the diamond substrate, the plurality of second grooves being spaced apart, and the plurality of first grooves and the plurality of second grooves being in a one-to-one correspondence and forming a plurality of cavities; and
disposing a device layer on the SiC intermediate layer.

14. The method for manufacturing the semiconductor structure according to claim 13, further comprising:
performing high-temperature heat treatment on the growth surface of the diamond substrate in a silane atmosphere, to form a silicon carbide coating layer.

15. The method for manufacturing the semiconductor structure according to claim 13, wherein the disposing a device layer on the SiC intermediate layer comprises:
disposing the device layer on the SiC intermediate layer, the device layer comprising a channel layer and a barrier layer that are stacked sequentially, and a source electrode, a drain electrode and a gate electrode that are located on the barrier layer.

16. The method for manufacturing the semiconductor structure according to claim 13, wherein the disposing a device layer on the SiC intermediate layer comprises:
disposing the device layer on the SiC intermediate layer, the device layer comprising a piezoelectric layer and an interdigital transducer that are stacked sequentially.

17. The method for manufacturing the semiconductor structure according to claim 13, wherein a surface crystal orientation of the diamond substrate comprises a [100] crystal orientation with a bias angle.

18. The method for manufacturing the semiconductor structure according to claim 17, wherein the bias angle ranges from 0° to 4°.

19. The method for manufacturing the semiconductor structure according to claim 13, wherein along a direction from the diamond substrate to the device layer, a depth of each first groove of the plurality of first grooves is less than or equal to a thickness of the diamond substrate.

20. The method for manufacturing the semiconductor structure according to claim 13, wherein on a plane where the diamond substrate is located, shapes of projections of the plurality of first grooves comprise at least one of triangle, square, hexagon, circle, strip shape, or mesh shape.
